(19) United States
(12) Patent Application Publication
(10) Pub. No.: US 2024/0215263 A1
(43) Pub. Date: Jun. 27, 2024

(54) MEMORY DEVICE COMPRISING LARGE CONTACT SURFACES BETWEEN THE CONDUCTION CHANNEL AND THE CONTACT REGIONS

(71) Applicant: COMMISSARIAT A L'ENERGIE ATOMIQUE ET AUX ENERGIES ALTERNATIVES, Paris (FR)

(72) Inventors: Sylvain BARRAUD, Grenoble Cedex (FR); Rémi COQUAND, Grenoble Cedex (FR); Shay REBOH, Grenoble Cedex (FR)

(73) Assignee: COMMISSARIAT A L'ENERGIE ATOMIQUE ET AUX ENERGIES ALTERNATIVES, Paris (FR)

(21) Appl. No.: 18/393,200

(22) Filed: Dec. 21, 2023

(30) Foreign Application Priority Data
Dec. 22, 2022 (FR) 22 14257

(51) Int. Cl. H10B 63/00

(52) U.S. Cl. CPC H10B 63/30; H10B 63/80

(57) ABSTRACT

A memory device (100) comprising at least one memory stack (158) electrically connected in series with a selection transistor, comprising:
a semiconductor layer (120) first areas (122) of which are superimposed and form a channel;
an electrostatic control gate (110) and a gate dielectric layer (112) such that parts of the gate dielectric layer are each arranged between a part (106, 108) of the gate and one of the first areas;
dielectric spacers (114) arranged against sidewalls of the gate;
contact regions (116, 118) electrically coupled to the first areas via second areas (124) of the semiconductor layer extending between the contact regions and the spacers, one of the contact regions (118) comprising the memory stack;
and wherein the second areas form a continuous layer with the first areas.

### TECHNICAL FIELD

The invention relates to the field of microelectronic devices applied to advanced CMOS technologies. In particular, the invention relates to memory devices, for example of the 1T1R, 1T1C, 2T1R, 2T1C type, of the OxRAM type (“Oxide Random Access Memory” in English, or oxide-based resistive memory) or FeRAM type (“Ferroelectric Random Access Memory” in English, or ferroelectric layer random access memory) or CBRAM type (“Conductive-Bridging Random Access Memory” in English, or conductive-bridge random access memory), and making of such memory devices.

### PRIOR ART

Electronics miniaturisation is constantly increasing, but the industry now approaches the scale limit for conventional materials such as silicon. Recently, 2D materials have emerged as promising candidates for use in miniature electronic and optoelectronic devices because of their unique properties and the very small thickness of the layers of these materials which could be made as a unique layer of atoms or molecules.

The document by K. P. O′Brien et al., “Advancing 2D Monolayer CMOS Through Contact, Channel and Interface Engineering,” 2021 IEEE International Electron Devices Meeting (IEDM), 2021, pp. 7.1.1-7.1.4, suggests making a MOSFET transistor by integrating a MoS₂ layer to form the conduction channel. This layer is connected to two metallic source and drain regions based on gold, palladium, TiN, tungsten or nickel. The rear gate is formed by a doped silicon layer positioned at the rear face beneath a dielectric layer based on SiO₂, HfO₂ or Al₂O₃.

In order to overcome the constraints related to the deposition of the metallic materials of the contact regions (conductive regions through which the conduction channel of the device is electrically accessible, and corresponding for example to the source and drain regions in the case of a transistor) over the 2D material, it is possible to form these regions not over the upper face of the 2D material layer, but against the sidewalls of the 2D material layer. Nonetheless, this configuration, so-called “side contact”, is problematic because the contact surface between the 2D material layer and the contact regions is small, which creates considerable contact resistances at the interfaces between the 2D material layer and the contact regions.

The document US 2022/045176 A1 describes several methods for making “gate-last” type FET transistors, wherein silicon portions serve as a support for the deposition of a 2D material layer. Besides the drawbacks related to the fact that the completed transistors have “side contact” type channel / source-drain interfaces, the silicon portions used to deposit the 2D material form a potential barrier at the interface with the 2D material, which is not desirable because a part for charges transport could be made in these silicon portions rather than in the 2D material.

These problems are also encountered in microelectronic devices other than FET transistors, like for example memory devices including a transistor.

### DISCLOSURE OF THE INVENTION

The present invention aims to provide a memory device which structure is compatible with any type of semiconductor material including 2D materials, and devoid of the drawbacks of a “side contact” configuration.

For this purpose, the present invention provides a memory device comprising at least one memory stack electrically connected in series with a selection transistor, the memory device comprising a substrate over which the selection transistor comprises:
a semiconductor layer comprising several first areas superimposed on top of one another, the first areas forming an electrical conduction channel of the selection transistor;
an electrostatic control gate and a gate dielectric layer of the selection transistor, parts of the gate dielectric layer being each arranged between a part of the electrostatic control gate and one of the first areas of the semiconductor layer;
dielectric spacers arranged against sidewalls of the electrostatic control gate;
contact regions electrically coupled to the first areas of the semiconductor layer via second areas of the semiconductor layer, the second areas of the semiconductor layer extending between the contact regions and the dielectric spacers, the contact regions forming source/drain regions of the selection transistor,
wherein one of the contact regions comprises the memory stack interposed between a first conductive portion, electrically connecting the memory stack to the semiconductor layer, and a second conductive portion forming an electrical contact of the memory stack;
and wherein the second areas of the semiconductor layer are not arranged directly against the electrostatic control gate and form a continuous layer with the first areas.

The proposed memory device is based on an architecture including no “side contact” type interface between the channel and the contact regions thanks to the second areas of the semiconductor layer achieving electrical coupling between the channel formed by the first areas of the semiconductor layer and the contact regions. These second areas of the semiconductor layer, which extend against at least part of the lateral walls, or sidewalls, of the contact regions, form a large contact surface with contact regions, which allows reducing the contact resistances of these contact regions. Thus, the electrical current circulating in the channel is not reduced because of these contact resistances, which does not reduce the performances of the device.

In addition, with the proposed architecture, the semiconductor layer may be made after the electrostatic control gate and before making the contact regions. Thus, the semiconductor layer including the first areas are intended to form the conduction channel is not deteriorated by the steps related to making of the electrostatic control gate. This is particularly advantageous when the semiconductor layer includes a 2D material.

Furthermore, making of such a device does not require keeping silicon portions for depositing the semiconductor layer intended to form the channel, thereby eliminating the problem of potential barrier at the interface with the material of the semiconductor layer. The memory device includes a “GAA stacked-nanosheet” type architecture, or an architecture with stacked nanosheets and a fully wrapped around gate.

In the memory device, one of the contact regions corresponds to an access electrode of the memory device, and the other contact region includes a memory stack, i.e. a stack of materials configured to record information. For example, such a memory stack corresponds to a MIM type (metal-insulator-metal) stack.

One or more of these contact regions may be common to several memory devices made over the same substrate.

The semiconductor layer may include a two-dimensional material or any other semiconductor material deposited by MOCVD (“Metal Organic Chemical Vapor Deposition”), CVD (“Chemical Vapor Deposition”) or ALD (“Atomic Layer Deposition”). In this case, the memory device may be made with very small dimensions.

The memory device may be such that:
each of the contact regions is arranged in a cavity comprising lateral walls formed at least by the dielectric spacers and by an insulating dielectric material;
the second areas of the semiconductor layer cover at least part of the walls of the cavities in which the contact regions are arranged.

In the configuration hereinabove, the contact surfaces of the contact regions with the semiconductor layer are maximised thanks to the use of the surface of the walls of the cavities, and advantageously, the entire surface of the walls of the cavity, to form the contact between the second areas of the semiconductor layer and the contact regions, which allows having very small contact resistances of these regions, and therefore a higher current flowing through the conduction channel of the device.

The selection transistor may be such that each of the first areas of the semiconductor layer may be surrounded by the same electrostatic control gate or by an electrostatic control gate different from that one surrounding the other areas of the semiconductor layer. In a first alternative, the selection transistor may further include one or more dielectric portion(s) each surrounded by one of the first areas of the semiconductor layer and such that each of the dielectric portions is surrounded by the first areas of the semiconductor layer. These dielectric portions may be intended to fill one or more space(s) between the first areas of the semiconductor layer.

In a second alternative, each of the first areas of the semiconductor layer does not surround the dielectric portion.

The selection transistor may further include inner dielectric spacers arranged against sidewalls of one or more part(s) of the electrostatic control gate. Such inner spacers are advantageous because they allow reducing parasitic capacitances within the device.

The memory stack may include a ferroelectric material layer or an oxide layer or an ionic layer.

The invention also relates to a microelectronic component including several memory devices as described before, and wherein:
the electrostatic control gates of the selection transistors of several memory devices are common and formed by the same material portions, and/or
one of the contact regions is common to two selection transistors of neighbouring memory devices.

The invention also relates to a method for making at least one memory device comprising at least one memory stack electrically connected in series with a selection transistor, comprising:
a) making, over a substrate, at least one alternating stack of portions of a first material and of portions of a second material, the first and second materials being able to be selectively etched with respect to each other, then
b) making a temporary gate covering a part of an upper face and of lateral faces of the stack, then
c) making dielectric spacers against sidewalls, or lateral walls, of the temporary gate, then
d) etching parts of the stack that are not covered with the temporary gate and the dielectric spacers, then
e) etching the temporary gate, then
f) etching the portions of the first material selectively with respect to the portions of the second material, then
g) making at least one part of an electrostatic control gate of the selection transistor in a space formed by etching of the temporary gate, such that the dielectric spacers are arranged against the sidewalls of the electrostatic control gate, then
h) etching the portions of the second material, then
i) making a semiconductor layer, advantageously a 2D material whose thickness may be comprised between 1 and 5 atomic units, comprising several first areas configured to form an electrical conduction channel of the selection transistor and arranged against the gate in locations formed by etching of the portions of the second material, the semiconductor layer extending, with no discontinuity with the first areas, while forming second areas covering at least part of the sidewalls of the dielectric spacers and which are not arranged directly against the electrostatic control gate, then
j) making, over the substrate, contact regions electrically coupled to the first areas of the semiconductor layer via the second areas of the semiconductor layer, each second area of the semiconductor layer extending between the contact regions and the dielectric spacers, the contact regions forming source/drain regions of the selection transistor, one of the contact regions including the memory stack interposed between a first conductive portion, electrically connecting the memory stack to the semiconductor layer, and a second conductive portion forming an electrical contact of the memory stack.

The method may further include, before implementation of step c), depositing an insulating dielectric material around the dielectric spacers, then etching cavities in the insulating dielectric material such that each of the cavities comprises at least one lateral wall formed by one of the dielectric spacers, and:
step i) may be implemented such that the second areas of the semiconductor layer cover at least part of the lateral walls of the cavities, and
step j) may be implemented such that each of the contact regions is arranged in one of the cavities. The method may further include a step of depositing a gate dielectric of the selection transistor implemented:
between steps f) and g), in the space formed by etching of the temporary gate, the electrostatic control gate of the selection transistor being in this case made over the gate dielectric, and/or
between steps h) and i), in the locations formed by etching of the portions of the second material, the semiconductor layer being in this case made by covering the gate dielectric. According to a first alternative, step i) may be implemented such that the first areas of the semiconductor layer cover walls of the locations formed by etching of the portions of the second material, and the method may further include, between steps i) and j), making dielectric portions in remaining spaces of the locations and such that each of the dielectric portions is surrounded by the first areas of the semiconductor layer.

According to a second alternative, step i) may be implemented such that the first areas of the semiconductor layer filling the locations formed by etching of the portions of the second material.

The method may further include, between steps d) and e), etching parts of the portions of the first material arranged directly above the dielectric spacers, and making inner dielectric spacers instead of the etched parts of the portions of the first material.

Throughout the entire document, the terms “over” and “under” are used regardless of the space orientation of the element to which this term relates. For example, in the feature “over a face of the first substrate”, this face of the first substrate is not necessarily oriented upwards but could correspond to a face oriented according to any direction. Furthermore, the arrangement of a first element over a second element should be understood as possibly corresponding to the arrangement of the first element directly against the second element, without any intermediate element between the first and second elements, or as possibly corresponding to the arrangement of the first element over the second element with one or more intermediate element(s) arranged between the first and second elements.

Throughout the entire document, the term “layer” may refer to one single layer or to a stack of several layers.

Throughout the entire document, the expression “electrically couple” is used to refer to an electrical connection which could be direct or which could be indirect (i.e. achieved through one or more intermediate electrical elements).

### BRIEF DESCRIPTION OF THE DRAWINGS

The present invention will be better understood upon reading the description of embodiments given for merely indicative and non-limiting purposes with reference to the appended drawings wherein:

FIG. 1

[symbol]

FIG. 2

[symbol]

FIG. 3

[symbol]

FIG. 4

[symbol]

FIG. 5

[symbol]

FIG. 6

[symbol]

FIG. 7

[symbol]

FIG. 8

[symbol]

FIG. 9

[symbol]

FIG. 10

[symbol]

FIG. 11

[symbol]

FIG. 12

[symbol]

FIG. 13

[symbol]

FIG. 14

[symbol]

FIG. 15 [symbol] , and

FIG. 16 schematically illustrate the steps of a method for making a memory device, object of the present invention, according to a particular embodiment;

FIG. 17

[symbol]

FIG. 18

[symbol]

FIG. 19 [symbol] , and

FIG. 20 schematically illustrate part of the steps of a method for making the memory device, object of the present invention, according to one variant.

Identical, similar or equivalent parts of the different figures described hereinafter bear the same reference numerals so as to facilitate switching from one figure to another.

The different parts shown in the figures are not necessarily plotted according to a uniform scale, to make the figures more readable.

The different possibilities (variants and embodiments) should not be understood as exclusive of one another and could be combined together.

### DETAILED DISCLOSURE OF PARTICULAR EMBODIMENTS

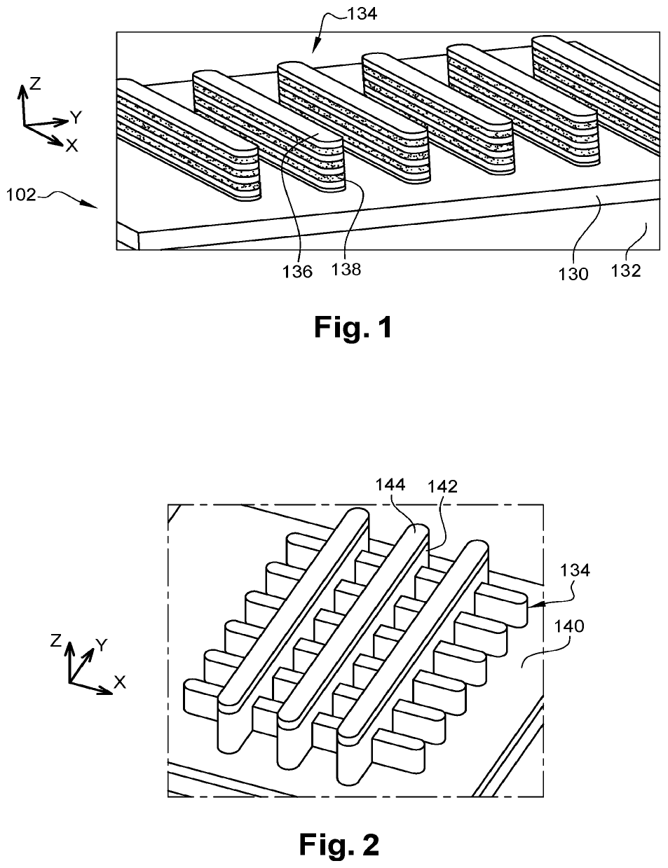

An example of a method for making a memory device 100 comprising at least one memory stack 158 electrically connected in series to a selection transistor, according to a particular embodiment is described hereinbelow with reference to FIGS. 1 to 16. In these figures, the simultaneous making of several memory devices 100 is shown, these devices belonging to an electronic component 1000.

An alternating stack of layers comprising a first material and a second material able to be selectively etched with respect to one another is carried out at first over a substrate 102. According to an advantageous example, the first and second materials respectively correspond to Si and SiGe. Other pairs of first and second materials are also possible: SiGe and Ge, Ge and GeSn, SiO₂ and amorphous silicon (a-Si). More generally, to form this alternation of layers of the first and second materials, it may be considered to use two semiconductors able to be selectively etched with respect to one another, or a dielectric material and an amorphous semiconductor.

The number of layers of this stack depends on the desired number of semiconductor material levels to form the channel of the device 100. In the embodiment described with reference to FIGS. 1 to 16, the stack of layers includes four silicon layers alternately stacked with here SiGe layers. Advantageously, the number of layers of the first material is comprised between 2 and 10, and the number of layers of the second material is comprised between 1 and 10.

For example, each of the layers of the stack has a thickness comprised between 5 nm and 25 nm, and for example equal to 12 nm.

In the embodiment described with reference to FIGS. 1 to 16, the substrate 102 corresponds to a SOI substrate, i.e. comprising a silicon superficial layer forming the first layer of the completed stack and which is arranged over a buried dielectric layer 130 comprising for example SiO₂. The buried dielectric layer 130 is arranged over a support layer 132 comprising silicon for example. Alternatively, the substrate 102 may correspond to a substrate of a type other than SOI, for example a “bulk” substrate, or bulk substrate, of a semiconductor (for example silicon).

Afterwards, etching of the completed stack of layers is implemented in order to form, over the substrate 102 (over the buried dielectric layer 130 in this example), at least one alternating stack 134 of portions 136 of the first material and of portions 138 of the second material. In FIG. 1, six distinct stacks 134 are shown, each comprising four portions 136 and three portions 138 alternately stacked on top of one another.

Each of the stacks 134 has a substantially elongate shape, i.e. includes a length (dimension according to the X axis) larger than its width (dimension according to the Y axis). The width of each stack 134 is for example comprised between 20 nm and 200 nm, and the length of each stack 134 is for example larger than 100 nm.

Afterwards, a thin dielectric layer 140, whose thickness is smaller than 10 nm and for example equal to 7 nm or 4 nm, is conformally deposited over the entire structure, i.e. while covering the upper faces and the lateral faces of the stacks 134 and the parts of the substrate 102 (of the buried dielectric layer 130 in the described embodiment) that are not covered with the stacks 134. For example, the dielectric layer 140 includes SiO₂ , which could be obtained starting from TEOS.

Afterwards, at least one temporary gate 142 is made, covering a part of an upper face and of the lateral faces of the stacks 134.

For this purpose, a material suitable for making the temporary gates is deposited over the entire structure. Advantageously, the deposited material is polycrystalline silicon. The thickness of the deposited material is larger than the sum of the thicknesses of one of the stacks 134 and of the dielectric layer 140, for example equal to 380 nm. Afterwards, a planarisation, for example a CMP (chemical-mechanical planarisation), of the deposited material is implemented so that a give thickness, for example equal to 70 nm, is kept above the stacks 134. Afterwards, a hard mask 144 is made over the remaining material after planarisation, the pattern of this hard mask defining that of the temporary gate(s) 142 to be made. For example, the hard mask 144 includes a semiconductor nitride/semiconductor oxide bilayer such as SiN/SiO₂. Afterwards, the remaining material suitable for making the temporary gates is etched in accordance with the pattern defined by the hard mask 144, forming the temporary gate(s) 142. In the described example, several temporary gates 142 are made (three temporary gates 142 are visible in FIG. 2, each formed by covering the six stacks 134).

For example, the width (dimension according to the X axis visible in FIG. 2) of each temporary gate 142 is for example comprised between 10 nm and several hundred nm, and the length (dimension according to the Y axis visible in FIG. 2) of each temporary gate 142 depends on the number of stacks 134 over which the temporary gates 142 should be made, and for example equal to several tens nm.

Afterwards, the dielectric spacers 114 are made against sidewalls of the temporary gates 142. For this purpose, a material layer suitable for making these spacers 114 is conformally deposited over the entire structure, i.e. while covering the upper faces and the lateral faces of the stacks 134, temporary gates 142 and hard masks 144 and the parts of the substrate 102 (of the buried dielectric layer 130 in the described embodiment) not covered with the stacks 134 and the temporary gates 142. For example, this material suitable for making the dielectric spacers 114 corresponds to SiN, SiCO or SiBCN. For example, the thickness of this layer is comprised between 5 nm and 15 nm.

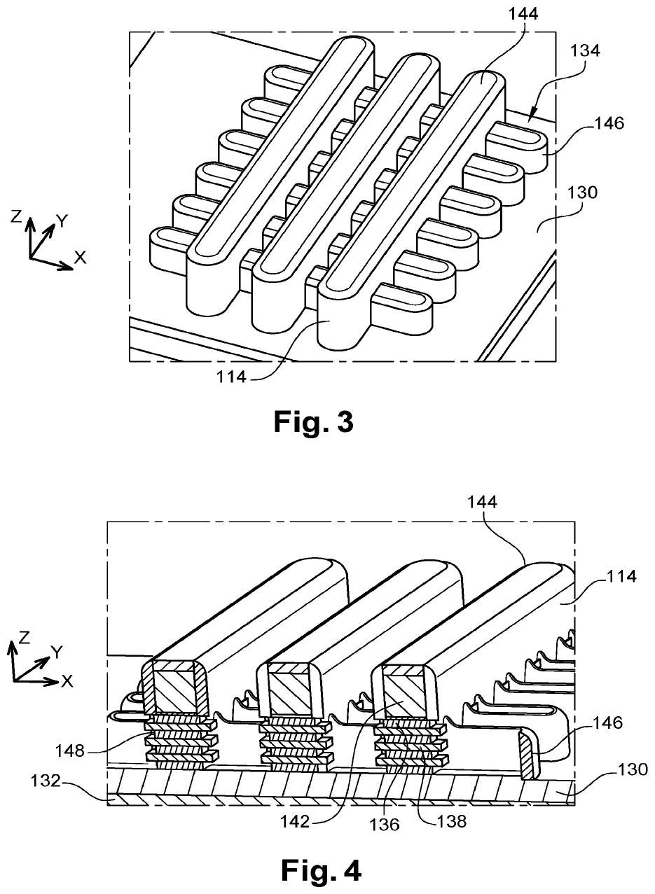

Afterwards, an anisotropic etching of this layer is implemented such that remaining portions of this layer arranged against the sidewalls of the temporary gates 142 form the dielectric spacers 114 (cf. FIG. 3). Remaining portions 146 of this layer arranged against the sidewalls of the stacks 134 may be preserved upon completion of this etching, or be advantageously eliminated. The anisotropic etching is implemented so as to eliminate the localised material over the upper faces of the temporary gates 142 and of the stacks 134. Furthermore, this etching also eliminates the parts of the layer 140 which are not covered with the temporary gates 142 and the dielectric spacers 114.

The parts of the stacks 134 that are not covered with the temporary gates 142, with the dielectric spacers 114 or with the remaining portions 146 are etched. This etching is stopped at the buried dielectric layer 130. Afterwards, the remaining parts of the portions 136 are partially and selectively etched with respect to the remaining parts of the portions 138, so as to form, directly above the dielectric spacers 114, spaces 148 above and below the ends of the remaining parts of the portions 138 (cf. FIG. 4). For example, the etched depth (dimension according to the X axis in FIG. 4) in the remaining parts of the portions 136 is comprised between 5 nm and 15 nm.

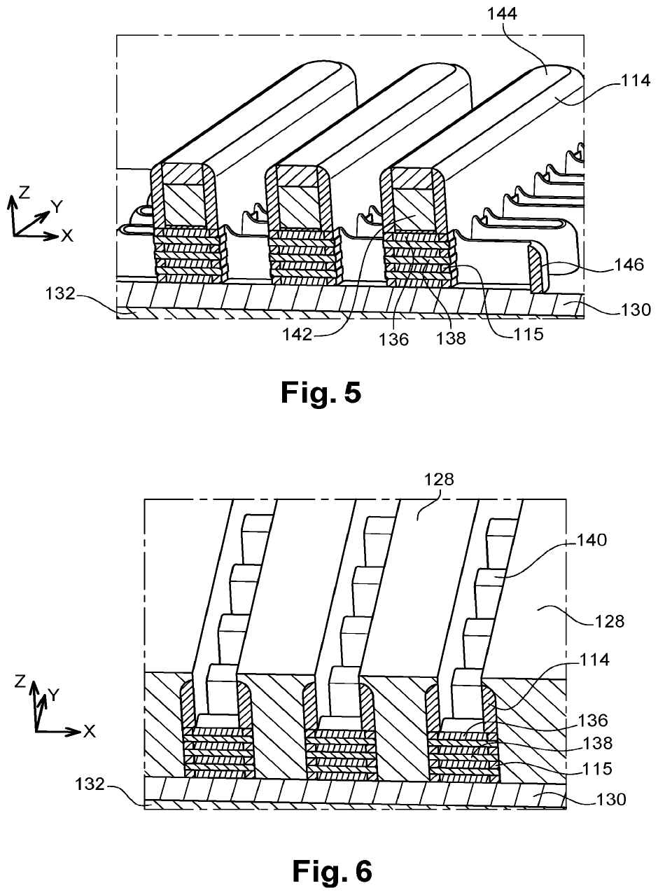

Afterwards, the inner dielectric spacers 115 are made in the previously formed spaces 148. These inner dielectric spacers 115 are obtained by depositing a dielectric material, for example SiN, SiBCN or SiCO so as to at least fill the spaces 148. The material deposited outside the spaces 148 is isotropically etched in order to keep only the inner dielectric spacers 115 (cf. FIG. 5).

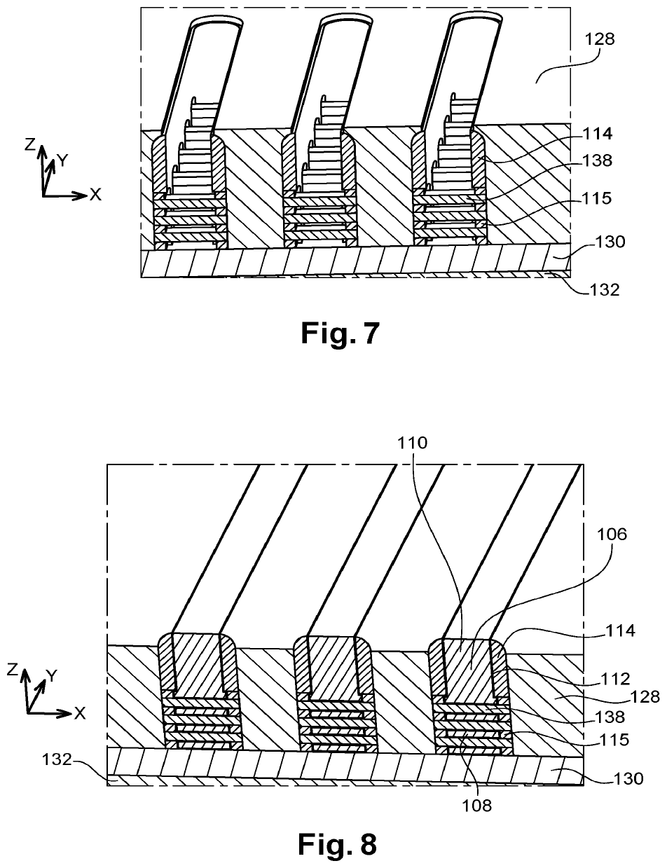

Afterwards, an insulating dielectric material 128, for example SiO₂, is deposited around the dielectric spacers 114. For this purpose, the insulating dielectric material 128 is deposited with a large thickness, then a planarisation is implemented until reaching the hard mask 144. Afterwards, the hard mask 144 is removed for example by wet etching, for example using a diluted H₃PO₄ solution used at a temperature of 110° C. Afterwards, the temporary gates 142 are removed, for example by etching using an HF solution diluted at 0.5% combined with an HCl solution diluted at 1% and with a TMAH solution at 5%. This etching is stopped when the remaining parts of the dielectric layer 140 are reached (cf. FIG. 6). Afterwards, the remaining parts of the dielectric layer 140 are etched, then the remaining parts of the portions 136 are selectively etched with respect to the remaining parts of the portions 138, for example by implementing a wet etching. The structure obtained at this level is shown in FIG. 7.

Afterwards, at least one layer 112 intended to form the gate dielectrics of the selection transistors of the memory devices 100 is conformally deposited, in particular in the spaces formed by etching of the temporary gates 142 while covering the walls formed by the dielectric spacers 114 and the remaining parts of the portions 138. For example, this layer includes for example a high-K dielectric material (with a high dielectric permittivity) such as HfO₂. Alternatively, this layer 112 intended to form the gate dielectrics may include SiO₂ or Al₂O₃ or any other suitable material or combination of materials.

Electrostatic control gates 110 of the selection transistors of the memory devices 100 are made by deposition of one or more conductive material(s) over the layer 112 intended to form the gate dielectrics of the selection transistors, through a first deposition of a thin TiN layer (for example a thickness equal to 3 nm) over which a tungsten layer with a thickness for example equal to 200 nm is stacked. In the example visible in FIG. 8, each of the gates 110 includes an upper part 106 and other parts 108 surrounding the remaining parts of the portions 138. The gates 110 could also include one or more material(s) other than TiN and W, like for example a doped polysilicon or any other metal (Mo, etc.).

Planarisation with stoppage at the insulating dielectric material 128 is implemented to eliminate the material(s) of the layer 112 intended to form the gate dielectrics and the electrostatic control gates 110 deposited outside the spaces formed by etching of the temporary gates 142.

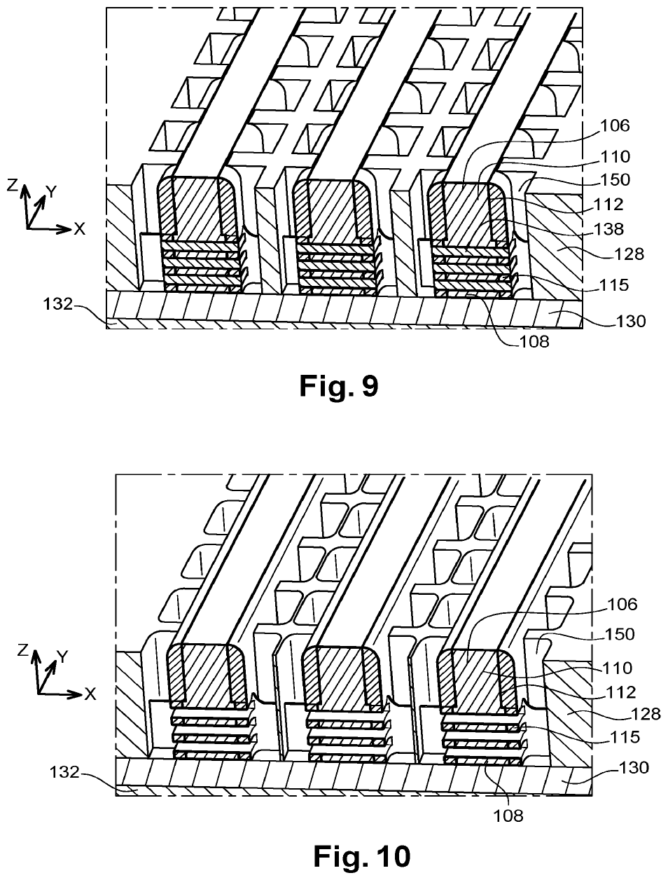

Afterwards, etching of a part of the insulating dielectric material 128 is implemented so as to form cavities 150 comprising lateral walls formed by the dielectric spacers 114, the inner dielectric spacers 115 and, in the example described herein, remaining portions of the insulating dielectric material 128 (cf. FIG. 9). These cavities 150 form locations for making the contact regions of the devices 100.

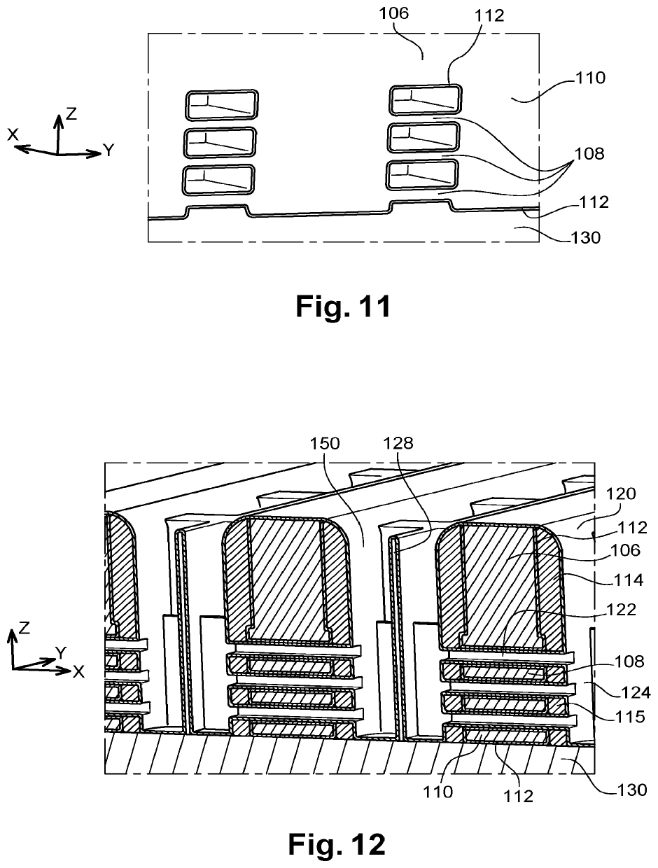

Afterwards, the portions 138 are etched, for example by implementation of a chemical etching using an Hf-H₂O₂ solution (cf. FIGS. 10 and 11) when the portions 138 include SiGe. As shown in FIG. 11 illustrating a sectional view according to the XX′ axis shown in FIG. 10, this etching forms tunnel-like shaped spaces in which the channels of the transistors are intended to be made.

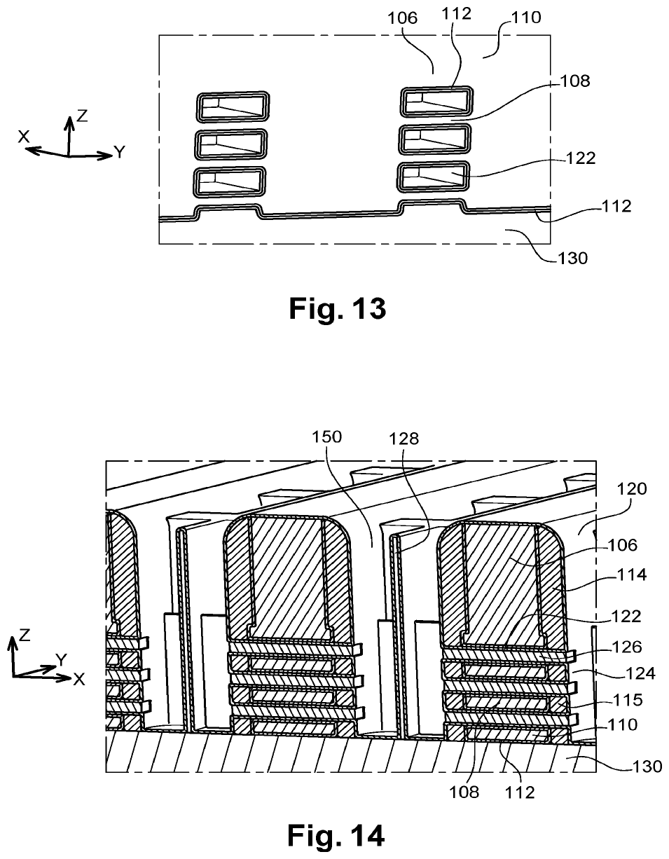

Afterwards, a semiconductor layer 120 is deposited over the entire structure made at this level of the method (cf. FIGS. 12 and 13). First areas 122 of this semiconductor layer 120 which are localised in the tunnel-like shaped spaces formed before are intended to form the channels of the selection transistors and are arranged against the gate dielectrics. Second areas 124 of this semiconductor layer 120 which cover the walls (lateral walls and bottom walls in the example described herein) of the cavities 150 are intended to be in contact with the contact regions which will be made afterwards. The deposition is carried out with no discontinuity, or with no interruption, between the first and second areas 122 and 124.

Advantageously, the semiconductor layer 120 includes at least one 2D semiconductor material, for example a dichalcogenide of transition metals such as MoS₂, or WSe₂, or WS₂, or MoTe₂. The material of the semiconductor layer 120 could also correspond to IGZO, In₂O₃, IWO, ITO, or an amorphous semiconductor oxide, or any other suitable semiconductor material.

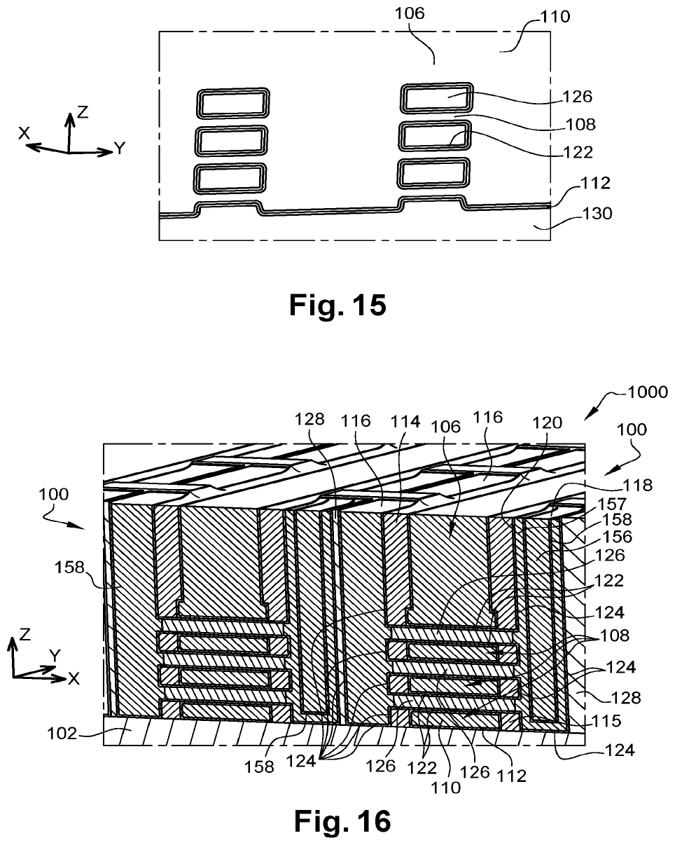

Afterwards, one or more dielectric layer(s), comprising for example Al₂O₃ (or HfO₂) and/or SiO₂ (or a low-k dielectric, or with a low dielectric permittivity), are deposited and then isotropically etched in order to keep only portions 126 localised in the tunnel-like shaped spaces (cf. FIGS. 14 and 15). These portions 126 form dielectric bars each surrounded by one of the first areas 122 of the semiconductor layer 120. Thus, the semiconductor layer 120 includes several first areas 122 superimposed on top of one another through a series of bars 126 and parts 108 of the gate 110 and of gate dielectrics.

Finally, contact regions 116, 118 are made by depositing, in the described example, one or more metallic material(s) in the cavities 150 (cf. FIG. 16). Before this or these metal deposition(s), it is possible to deposit a graphene layer in the cavities 150, this or these metal(s) being deposited afterwards over the graphene layer. Advantageously, the contact regions 116, 118 include at least one metallic material such as gold, palladium, TiN, W, Ni, etc. According to one embodiment, each of the contact regions 116, 118 includes a TiN layer over which a tungsten portion is formed. Different metals may be used to form the contact regions 116, 118 in order to favour low contact resistances like for example: S, Bi, Sn, Pd, Ru, Cu, Ni, Ti, TiN, W, Au, etc. These materials may also be subsequently modified (to improve their properties), in a doping step for example. These contact regions 116, 118 form the source/drain regions of the selection transistors of the memory devices 100.

Furthermore, the contact region 118 includes a memory stack 158, i.e. a stack of materials in which it is possible to record information. This memory stack 158 may correspond to a stack of materials of the FeRAM type including in this case a ferroelectric material layer, or OxRAM type including in this case an oxide layer, or CBRAM type including in this case an ionic layer, for example a MIM-type stack (metal-insulator-metal).

This memory stack 158 is arranged within the metallic material(s) forming the remainder of the contact region 118. Part of the metallic material(s) is interposed between the memory stack 158 and the parts of the semiconductor layer 120 localised in the cavity 150 in which the contact region 118 is made. Thus, the memory stack 158 is interposed between a first conductive portion 157 of the contact region 118, electrically connecting the memory stack 158 to the semiconductor layer 120, and a second conductive portion 156 of the contact region 118 forming an electrical contact of the memory stack 158.

These contact regions 116 and 118 are therefore electrically coupled to the first areas 122 of the semiconductor layer 120 via the second areas 124 of the semiconductor layer 120 which extend between the contact regions 116, 118 and the dielectric pacers 114 as well as against the other walls of the contact regions 116, 118 localised in the cavities 150. The material of these regions deposited outside the cavities 150 is eliminated by implementation of a planarisation with stoppage at the insulating dielectric material 128. The devices obtained upon completion of this method correspond to the devices 100 shown in FIG. 16.

In the previously-described embodiment, the semiconductor layer 120 does not completely fill the spaces formed by etching of the portions 138, and dielectric portions 126 are made in the remaining spaces after deposition of the semiconductor layer 120.

According to a first variant, it is possible not to make the dielectric portions 126, the semiconductor layer 120 filling in this case, upon deposition thereof, the remaining spaces formed by etching of the portions 138. In this case, one could observe the formation of air gaps, i.e. recesses or empty spaces, in the first areas 122 of the semiconductor layer 120. Nevertheless, these air gaps do not prevent continuity between the first areas 122 and the second areas 124 of the semiconductor layer 120.

According to another variant (which is compatible with the first variant hereinabove), it is possible that the layer 112 forming the gate dielectric of the selection transistor of the memory device 100 is not deposited just before making of the gate 110 as previously described, but that this layer is deposited in the spaces formed by etching of the portions 138 and in the cavities 1150, just before deposition of the semiconductor layer 120. In this case, the layer 112 covers the different walls over which the material of the semiconductor layer 120 is intended to be deposited, thereby homogenising the surfaces, and therefore the interfaces, against which the semiconductor layer 120 is deposited afterwards.

According to another variant (which is compatible with the above-described first variant), the layer 112 could be deposited in two different steps: first of all just before making of the gate 110 as previously described with reference to FIG. 8, then in the spaces formed by etching of the portions 138 and in the cavities 150, just before deposition of the semiconductor layer 120. In this case, the parts of the layer 112 localised directly above the gate 110 are thicker than the other parts of the layer 112 because these parts cumulate the material thicknesses deposited during the two deposition steps.

In the previously-described embodiment, all of the lateral walls of the cavities 150 are covered with the second areas 124 of the semiconductor layer 120. Alternatively, it is possible that only part of these lateral walls is covered with the second areas 124.

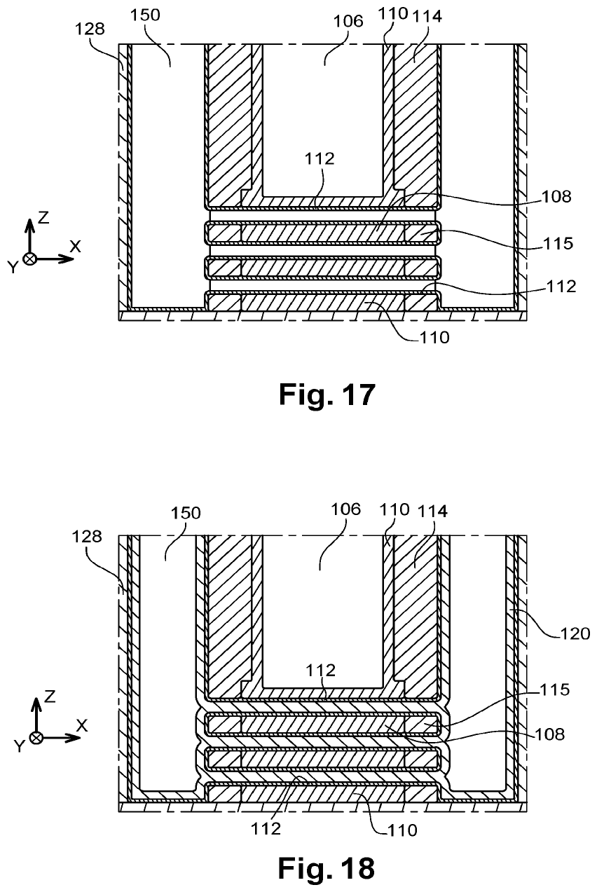

FIGS. 17 to 20 schematically show part of the steps of the implemented method combining the above-described two variants.

The steps previously described with reference to FIGS. 1 to 12 are implemented at first. Afterwards, unlike the previous embodiment wherein the semiconductor layer 120 is deposited, the layer 112 forming the gate dielectrics, advantageously comprising a high-K dielectric material such that HfO₂, is deposited over the entire structure (cf. FIG. 17). Parts of this layer 112 are localised in the tunnel-like shaped spaces formed before, thereby forming the gate dielectrics, and other parts of this layer 112 covering the walls of the cavities 150.

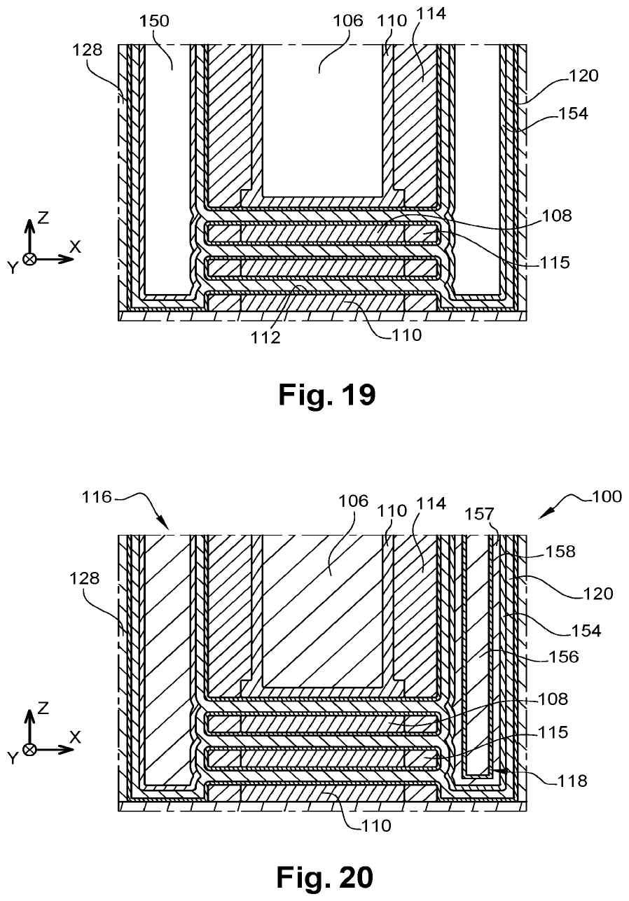

Afterwards, the semiconductor layer 120 is deposited over the entire structure, while covering the layer 112 forming the gate dielectrics (cf. FIG. 18), so as to completely fill the remaining spaces in the form of tunnels. The cavities 150 are not completely filled by deposition of the semiconductor layer 120 and the layer 112 forming the gate dielectrics. Afterwards, the contact regions 116, 118 are made, for example by carrying out a first deposition (for example ALD) of TiN (bearing the reference 154 in FIG. 19), then by filling the remainder of the available space with tungsten (bearing the reference 156 in FIG. 20). In the example described herein, this tungsten deposition also completes making of the control gate 110. Furthermore, during the tungsten deposition, the latter is stopped to make the memory stack 158 within the contact region 118, then carried on to complete making of the contact regions 116, 118.

One of the variants hereinabove may be implemented without the other being so. For example, it is possible to deposit the layer 112 forming the gate dielectric in the spaces formed by etching of the portions 138, before deposition of the semiconductor layer 120, and that empty spaces are still present after deposition of the semiconductor layer 120. In this case, the dielectric portions 126 may be made as previously described with reference to FIGS. 14 and 15.

In the embodiment shown in FIG. 16, the control gate 110 is common to several devices 100, i.e. simultaneously controls these different devices, whose contact regions 116, 118 are electrically insulated from those of the other neighbouring devices 100 by portions of the insulating dielectric material 128. Alternatively, it is possible that the completed gates 110 are not common to the different completed devices 100.

Furthermore, each of the first areas 122 of the semiconductor layer 120 may be surrounded by the same electrostatic control gate 110, as is the case in the previously-described examples, or by an electrostatic control gate different from that one surrounding the other first areas 122 of the semiconductor layer 120.

In the embodiment shown in FIG. 16, each of the contact regions 116, 118 is arranged in a cavity comprising lateral walls formed by the dielectric spacers 114, 115 and by an insulating dielectric material 128. In this configuration, the second areas 124 of the semiconductor layer 120 cover the lateral walls and the bottom walls of the cavities in which the contact regions 116, 118 are arranged.

Alternatively, some contact regions could be common to several devices 100. For example, for two adjacent devices 100, the insulating dielectric material 128 could be absent for the same region contact, for example the contact region 118 including the memory stack 158, to be electrically coupled to the channels of these two neighbouring devices 100. For example, such a configuration allows making 2T1R or 2T1C type memory devices.

1. A memory device (100) comprising at least one memory stack (158) electrically connected in series with a selection transistor, the memory device (100) comprising a substrate (102) over which the selection transistor comprises:
a semiconductor layer (120) comprising several first areas (122) superimposed on top of one another, the first areas (122) forming an electrical conduction channel of the selection transistor;
an electrostatic control gate (110) and a gate dielectric layer (112) of the selection transistor, parts of the gate dielectric layer (112) being each arranged between a part (106, 108) of the electrostatic control gate (110) and one of the first areas (122) of the semiconductor layer (120);
dielectric spacers (114) arranged against sidewalls of the electrostatic control gate (110);
contact regions (116, 118) electrically coupled to the first areas (122) of the semiconductor layer (120) via second areas (124) of the semiconductor layer (120), the second areas (124) of the semiconductor layer (120) extending between the contact regions (116, 118) and the dielectric spacers (114), the contact regions (116, 118) forming source/drain regions of the selection transistor.
wherein one of the contact regions (118) comprises the memory stack (158) interposed between a first conductive portion (157), electrically connecting the memory stack (158) to the semiconductor layer (120), and a second conductive portion (156) forming an electrical contact of the memory stack (158);
and wherein the second areas (124) of the semiconductor layer (120) are not arranged directly against the electrostatic control gate (110) and form a continuous layer with the first areas (122).

2. The memory device (100) according to claim 1, wherein the semiconductor layer (120) includes a two-dimensional material or any other semiconductor material deposited by MOCVD, CVD or ALD.

3. The memory device (100) according to claim 1, wherein:
each of the contact regions (116, 118) is arranged in a cavity (150) comprising lateral walls formed at least by the dielectric spacers (114) and by an insulating dielectric material (128);
the second areas (124) of the semiconductor layer (120) cover at least part of the walls of the cavities (150) in which the contact regions (116, 118) are arranged.

4. The memory device (100) according to claim 1, wherein the selection transistor is such that each of the first areas (122) of the semiconductor layer (120) is surrounded by the same electrostatic control gate (110) or by an electrostatic control gate (110) different from that one surrounding the other areas (122) of the semiconductor layer (120).

5. The memory device (100) according to claim 1, wherein the selection transistor further includes one or more dielectric portion(s) (126) each arranged between two first areas (122) of the semiconductor layer (120) and such that each of the dielectric portions (126) is surrounded by the first areas (122) of the semiconductor layer (120).

6. The memory device (100) according to claim 1, wherein the selection transistor further includes inner dielectric spacers (115) arranged against sidewalls of one or more parts (108) of the electrostatic control gate (110).

7. The memory device (100) according to claim 1, wherein the memory stack (158) includes a ferroelectric material layer or an oxide layer or an ionic layer.

8. A microelectronic component (1000) including several memory devices (100) according to claim 1, and wherein:
the electrostatic control gates (110) of the selection transistors of several memory devices (100) are common and formed by the same material portions, and/or
one of the contact regions (116, 118) is common to two selection transistors of neighbouring memory devices (100).

9. A method for making a memory device (100) comprising at least one memory stack (158) electrically connected in series with a selection transistor, comprising:
a) making, over a substrate (102), at least one alternating stack (134) of portions of a first material (136) and of portions of a second material (138), the first and second materials being able to be selectively etched with respect to each other, then
b) making a temporary gate (142) covering a part of an upper face and of lateral faces of the stack (134), then
c) making dielectric spacers (114) against sidewalls of the temporary gate (142), then
d) etching parts of the stack (134) that are not covered with the temporary gate (142) and the dielectric spacers (114), then
e) etching the temporary gate (142), then
f) etching the portions of the first material (136) selectively with respect to the portions of the second material (138), then
g) making at least one part of an electrostatic control gate (110) of the selection transistor in a space formed by etching of the temporary gate (142), such that the dielectric spacers (114) are arranged against the sidewalls of the electrostatic control gate (110), then
h) etching the portions of the second material (138), then
i) making a semiconductor layer (120) comprising several first areas (122) configured to form an electrical conduction channel of the selection transistor and arranged against the gate (110) in locations formed by etching of the portions of the second material (138), the semiconductor layer (120) extending, with no discontinuity with the first areas (122), while forming second areas (124) covering at least part of the sidewalls of the dielectric spacers (114) and which are not arranged directly against the electrostatic control gate (110), then
j) making, over the substrate (102), contact regions (116, 118) electrically coupled to the first areas (122) of the semiconductor layer (120) via the second areas (124) of the semiconductor layer (120), each second area (124) of the semiconductor layer (120) extending between the contact regions (116, 118) and the dielectric spacers (114), the contact regions (116, 118) forming source/drain regions of the selection transistor, one of the contact regions (118) including the memory stack (158) interposed between a first conductive portion (157), electrically connecting the memory stack (158) to the semiconductor layer (120), and a second conductive portion (156) forming an electrical contact of the memory stack (158), wherein the method further includes making a gate dielectric layer of the selection transistor such that parts of the gate dielectric layer are each arranged between a part of the electrostatic control gate and one of the first areas of the semiconductor layer.

10. The method according to claim 9, further including, between steps d) and e), depositing an insulating dielectric material (128) around the dielectric spacers (114), then etching cavities (150) in the insulating dielectric material (128) such that each of the cavities (150) comprises at least one lateral wall formed by one of the dielectric spacers (114), and wherein:
step i) is implemented such that the second areas (124) of the semiconductor layer (120) cover at least part of the lateral walls of the cavities (150), and
step j) is implemented such that each of the contact regions (116, 118) is arranged in one of the cavities (150).

11. The method according to claim 9, including a step of depositing the gate dielectric layer (112) of the selection transistor implemented:
between steps f) and g), in the space formed by etching of the temporary gate (142), the electrostatic control gate (110) of the selection transistor being in this case made over the gate dielectric layer (112), and/or
between steps h) and i), in the locations formed by etching of the portions of the second material (138), the semiconductor layer (120) being made afterwards by covering the gate dielectric layer (112).

12. The method according to claim 9, wherein step i) is implemented such that the first areas (122) of the semiconductor layer (120) cover walls of the locations formed by etching of the portions of the second material (138), and the method further includes, between steps i) and j), making dielectric portions (126) in remaining spaces of the locations and such that each of the dielectric portions (126) is surrounded by the first areas (122) of the semiconductor layer (120).

13. The method according to claim 9, wherein step i) is implemented such that the first areas (122) of the semiconductor layer (120) filling the locations formed by etching of the portions of the second material (138).

14. The method according to claim 9, further including, between steps d) and e), etching parts of the portions of the first material (136) arranged directly above the dielectric spacers (114), and making inner dielectric spacers (115) instead of the etched parts of the portions of the first material (136).
